(19) United States
(12) Patent Application Publication
(10) Pub. No.: US 2003/0017710 A1
(43) Pub. Date: Jan. 23, 2003

(54) Method to improve latchup by forming selective sloped staircase STI structure to use in the I/0 or latchup sensitive area

(75) Inventors: Pan Yang, Singapore (SG); James Lee Yong Meng, Singapore (SG); Leung Ying Keung, Hong Kong (HK); Yelehanka Ramachandramurthy Pradeep, Singapore (SG); Jia Zhen Zheng, Singapore (SG); Lap Chan, San Francisco, CA (US); Elgin Quek, Singapore (SG); Ravi Sundaresan, San Jose, CA (US)

Correspondence Address: GEORGE O. SAILE & ASSOCIATES, 28 DAVIS AVENUE, POUGHKEEPSIE, NY, 12603, US

(73) Assignee: Chartered Semiconductor Manufacturing Ltd.

(21) Appl. No.: 09/907,649

(22) Filed: Jul. 19, 2001

(51) Int. Cl. C23F 1/00; C03C 15/00; H01L 21/461

(52) U.S. Cl. 438/718; 216/41; 216/13

(57) ABSTRACT

A method of forming a sloped staircase STI structure, comprising the following steps. a) A substrate having an upper surface is provided. b) A patterned masking layer is formed over the substrate to define an STI region. The patterned masking layer having exposed sidewalls. c) The substrate is etched a first time through the masking layer to form a first step trench within the STI region. The first step trench having exposed sidewalls. d) Continuous side wall spacers are formed on the exposed patterned masking layer and first step trench sidewalls. e) The substrate is etched a second time using the masking layer and the continuous sidewall spacers as masks to form a second step trench within the STI region. The second step trench having exposed sidewalls. f) Second side wall spacers are formed on the second step trench sidewalls. g) Steps e) and f) are repeated x more times to create x+2 total step trenches and x+2 total side wall spacers on x+2 total step trench sidewalls. h) A planarized STI is formed within the STI region substantially level with the substrate upper surface and over the x+2 total step trenches.

### FIELD OF THE INVENTION

The present invention relates generally to forming isolation structures in semiconductor devices, and more specifically to methods forming shallow trench isolation (STI) in semiconductor devices.

### BACKGROUND OF THE INVENTION

Latchup is a parasitic circuit effect, the result of which is the shorting of the V_{DD} and V_{SS} lines that usually results in chip self-destruction or at least system failure with the requirement to power down. Latchup effects will become severe when the VLSI circuit dimension is scaled.

U.S. Pat. No. 5,904,540 to Sheng et al. describes a shallow trench isolation (STI) process to form a one step STI structure using a trench etch with spacers on the trench sidewalls.

U.S. Pat. No. 5,298,450 to Verret and U.S. Pat. No. 5,371,036 to Lur et al. each describe an STI process that forms a one step STI structure.

U.S. Pat. No. 5,866,435 to Park describes an STI process that uses spacers to form a curved surface.

U.S. Pat. No. 4,495,025 to Haskell describes a process for forming grooves of different depths using spacers.

U.S. Pat. No. 5,795,811 to Kim et al. describes an STI process for forming an isolating trench device with spacers in a semiconductor device.

### SUMMARY OF THE INVENTION

Accordingly, it is an object of the present invention to provide a method of reducing latchup effect in semiconductor devices.

Another object of the present invention to provide a method of reducing latchup effect in semiconductor devices by extending the effective basewidth of shallow trench isolation (STI) structures.

Other objects will appear hereinafter.

It has now been discovered that the above and other objects of the present invention may be accomplished in the following manner. Specifically, the following steps are performed: a) A substrate having an upper surface is provided. b) A patterned masking layer is formed over the substrate to define an STI region. The patterned masking layer having exposed sidewalls. c) The substrate is etched a first time through the masking layer to form a first step trench within the STI region. The first step trench having exposed sidewalls. d) Continuous side wall spacers are formed on the exposed patterned masking layer and first step trench sidewalls. e) The substrate is etched a second time using the masking layer and the continuous sidewall spacers as masks to form a second step trench within the STI region. The second step trench having exposed sidewalls. f) Second side wall spacers are formed on the second step trench sidewalls. g) Steps e) and f) are repeated x more times to create x+2 total step trenches and x+2 total side wall spacers on x+2 total step trench sidewalls. h) A planarized STI is formed within the STI region substantially level with the substrate upper surface and over the x+2 total step trenches.

### BRIEF DESCRIPTION OF THE DRAWINGS

The features and advantages of the present invention will be more clearly understood from the following description taken in conjunction with the accompanying drawings in which like reference numerals designate similar or corresponding elements, regions and portions and in which:

FIGS. 1 to 15 schematically illustrate in cross-sectional representation a preferred embodiment of the present invention.

### DETAILED DESCRIPTION OF THE PREFERRED EMBODIMENT

The inventors have determined that it is desirable to extend effective basewidth to reduce Beta (β) and to improve latchup immunity. Beta being the current gain of the parasitic bipolar transistor which is composed of source/drain, well and substrate in a CMOS structure.

Unless otherwise specified, all structures, layers, etc. may be formed or accomplished by conventional methods known in the prior art.

Definition of STI Region 14

Accordingly as shown in FIG. 1, starting semiconductor substrate 10 is understood to include an upper silicon layer, and may be a silicon substrate.

Masking layer 12 is formed and patterned over semiconductor substrate 10 at least proximate STI region 14 to define at least one shallow trench isolation (STI) region 14. Masking layer 12 may be formed of nitride, silicon nitride or polysilicon, and is preferably silicon nitride as will be used as example hereafter. Nitride layer 12 is preferably from about 500 to 2000 Å thick, and is more preferably from about 1000 to 1500 Å thick.

STI region 14 is preferably from about 1500 to 10,000 Å wide and is more preferably from about 1000 to 5000 Å wide.

STI region 14 separates one or more active regions 16 (see FIG. 15), with an STI region 14 adjacent each active region 16.

Formation of First Step Trench 18

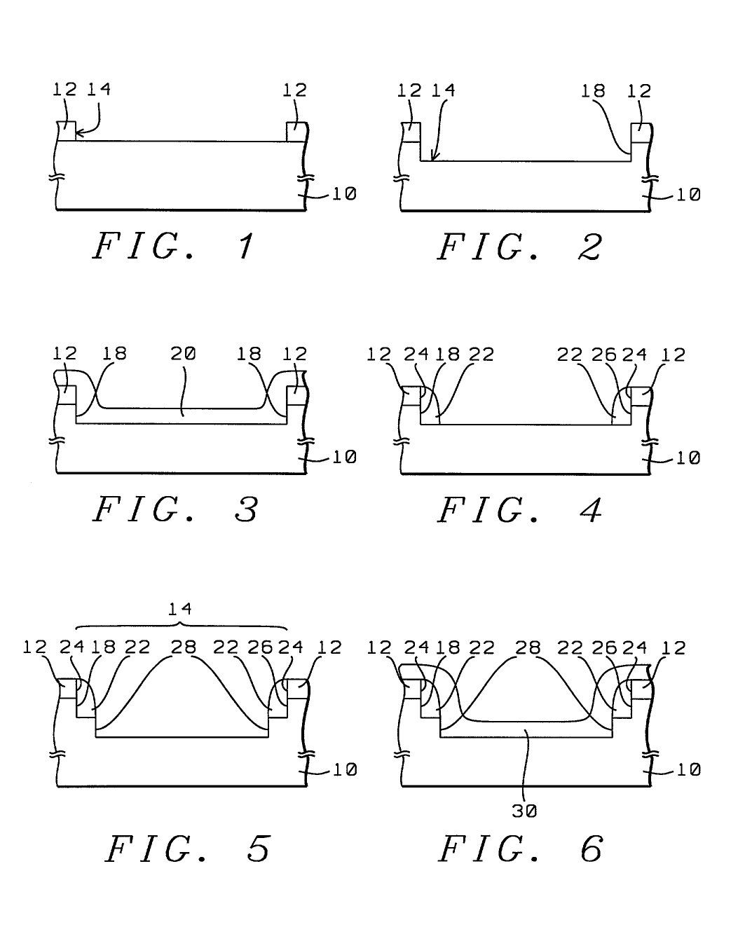

As shown in FIG. 2, using patterned nitride layer 12 as a mask, silicon substrate 10 is etched to form first step trench 18. First step trench 18 is preferably from about 1000 to 4000 Å deep from the top of etched silicon substrate 10 and is more preferably from about 2000 to 3000 Å.

As shown in FIG. 3, first silicon oxide (oxide) layer 20 is preferably selectively deposited over STI region 14 and patterned nitride layer 12, and at least partially fills first step trench 18. First oxide layer 20 is preferably from about 300 to 1000 Å thick above patterned nitride layer 12, and more preferably from about 400 to 600 Å thick.

As shown in FIG. 4, first oxide layer 20 is then etched to form first step oxide spacers 22 adjacent patterned nitride layer 12 sidewalls 24 and first step trench sidewalls 26.

The base of first step oxide spacers 22 is preferably from about 300 to 1000 Å wide and is more preferably from about 400 to 600 Å wide.

Formation of Second Step Trench 28

As shown in FIG. 5, using patterned nitride layer 12 and first step oxide spacers 22 as a mask, silicon substrate 10 is etched to form second step trench 28. Second step trench 28 is preferably from about 500 to 2000 Å deep below first step trench 18 and is more preferably from about 800 to 1500 Ådeep.

As shown in FIG. 6, second silicon oxide (oxide) layer 30 is preferably selectively deposited over STI region 14, patterned nitride layer 12, and first step oxide spacers 22, and at least partially fills first and second step trenches 18, 28. Second oxide layer 30 is preferably from about 300 to 1000 Å thick above patterned nitride layer 12, and more preferably from about 400 to 600 Å thick.

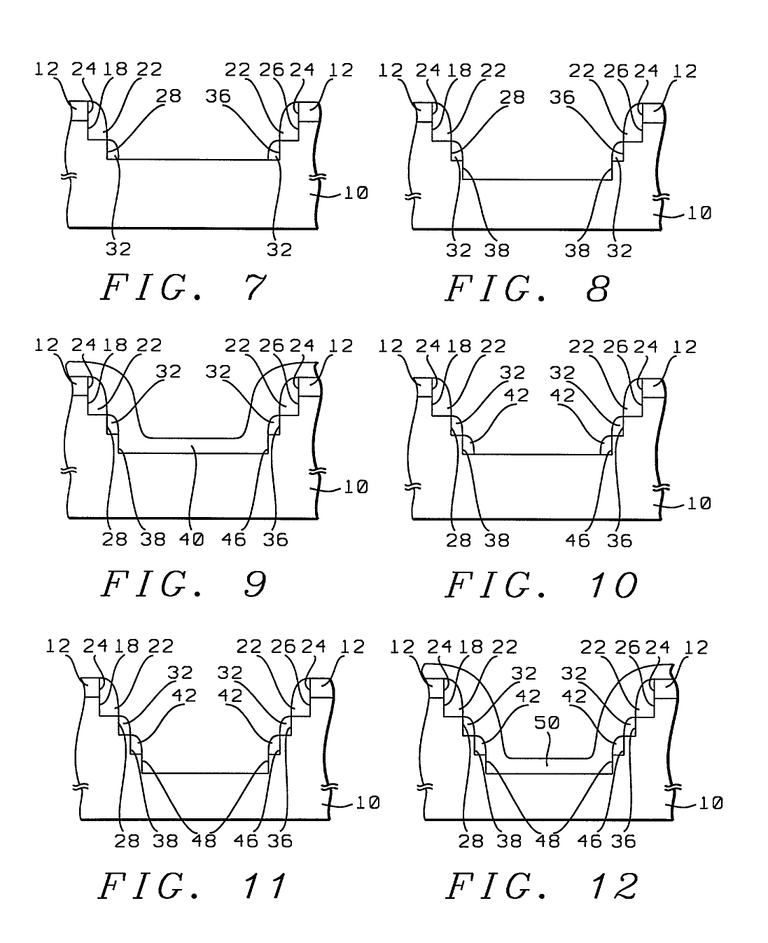

As shown in FIG. 7, second oxide layer 30 is then etched to form second step oxide spacers 32 adjacent second step trench sidewalls 36.

The base of second step oxide spacers 32 is preferably from about 300 to 1000 Å wide and is more preferably from about 400 to 600 Å wide.

Formation of Third Step Trench 38

As shown in FIG. 8, using patterned nitride layer 12, first step oxide spacers 22, and second step oxide spacers 32 as a mask, silicon substrate 10 is etched to form third step trench 38. Third step trench 38 is preferably from about 500 to 2000 Å deep below second step trench 28, more preferably from about 800 to 1500 Ådeep, and most preferably form about 400 to 600Å deep.

As shown in FIG. 9, third silicon oxide (oxide) layer 40 is preferably selectively deposited over STI region 14, patterned nitride layer 12, first step oxide spacers 22, and second step oxide spacers 32, and at least partially fills first, second, and third step trenches 18, 28, 38. Third oxide layer 40 is preferably from about 300 to 1000 Å thick above patterned nitride layer 12, and more preferably from about 400 to 600 Å thick.

As shown in FIG. 10, third oxide layer 40 is then etched to form third step oxide spacers 42 adjacent third step trench sidewalls 46.

The base of third step oxide spacers 42 is preferably from about 300 to 1000 Å wide and is more preferably from about 400 to 600 Å wide.

Formation of Fourth Step Trench 48

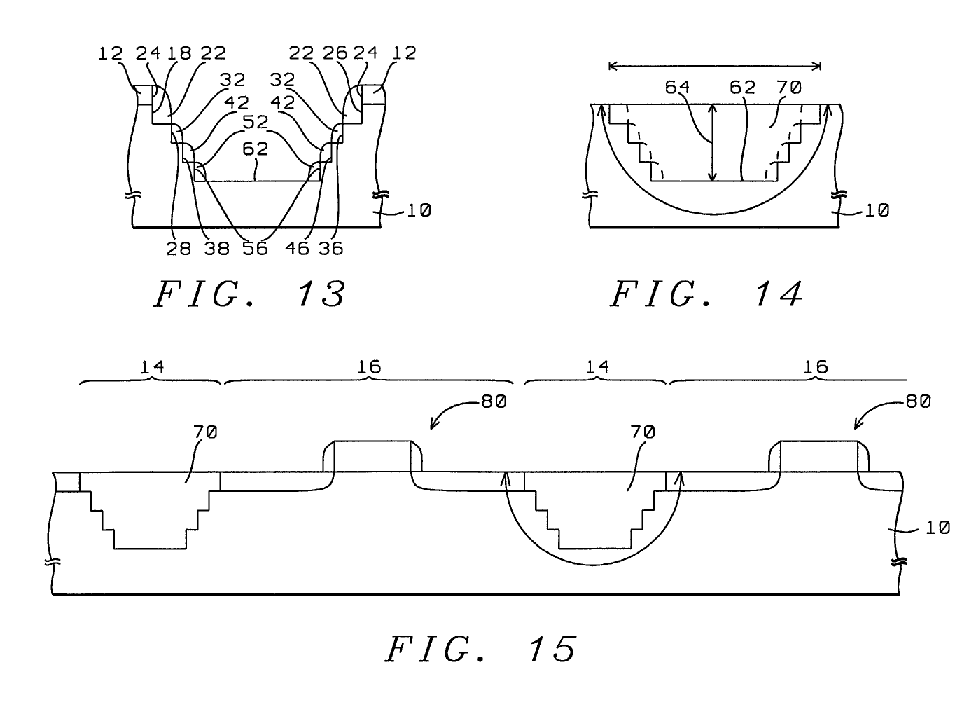

As shown in FIG. 11, using patterned nitride layer 12, first step oxide spacers 22, second step oxide spacers 32, and third step oxide spacers 42 as a mask, silicon substrate 10 is etched to form fourth step trench 48. Fourth step trench 48 is preferably from about 500 to 2000 Å deep below third step trench 38, more preferably from about 800 to 1500 Å deep, and most preferably from about 400 to 600 Å deep.

As shown in FIG. 12, fourth silicon oxide (oxide) layer 50 is preferably selectively deposited over STI region 14, patterned nitride layer 12, first step oxide spacers 22, second step oxide spacers 32, and third step oxide spacers 42, and at least partially fills first, second, third, and fourth step trenches 18, 28, 38, 48. Fourth oxide layer 50 is preferably from about 300 to 1000 Å thick above patterned nitride layer 12, and more preferably from about 400 to 600 Å thick.

As shown in FIG. 13, fourth oxide layer 50 is then etched to form fourth step oxide spacers 52 adjacent fourth step trench sidewalls 56.

The base of fourth step oxide spacers 52 is preferably from about 300 to 1000 Å wide and is more preferably from about 400 to 600 Å wide.

Formation of STI 70

Although the present invention has, for example, described the formation of four step trenches and respective step oxide spacers, less or additional step trenches with their respective step oxide spacers may be formed.

As shown in FIG. 14, once the predetermined number of step trenches and respective step oxide spacers have been formed, a last layer of oxide is selectively deposited over the structure encompassing STI region 14 and patterned nitride layer 12, completely filling, in the illustrated example, first, second, third, and fourth step trenches 18, 28, 38, 48 with their respective first, second, third, and fourth step oxide spacers 22, 32, 42, 52. Patterned nitride layer 12 is removed, and the last oxide layer is planarized to form STI 70.

By fabricating the sloped, stepped staircase STI structure 70 of the present invention, the basewidth 74 of STI structure 70 is effectively extended which reduces Beta and improves latchup immunity for the chips including STI structures 70. This reduces system failure and the requirement to power down.

As shown in FIG. 15, STIs 70 formed in accordance with the present invention are formed between semiconductor devices 80 within active areas 16, to isolate devices 80 form each other.

While particular embodiments of the present invention have been illustrated and described, it is not intended to limit the invention, except as defined by the following claims.

We claim:

1. A method of forming a sloped staircase STI structure, comprising the steps of:
a) providing a substrate having an upper surface;
b) forming a patterned masking layer over said substrate to define an STI region; said patterned masking layer having exposed sidewalls;
c) etching said substrate a first time through said masking layer to form a first step trench within said STI region; said first step trench having exposed sidewalls;
d) forming continuous side wall spacers on said exposed patterned masking layer and first step trench sidewalls;
e) etching said substrate a second time using said masking layer and said continuous sidewall spacers as masks to form a second step trench within said STI region; said second step trench having exposed sidewalls;
f) forming second side wall spacers on said second step trench sidewalls;
g) repeating steps e) and f) x more times to create x+2 total step trenches and x+2 total side wall spacers on x+2 total step trench sidewalls; and
h) forming a planarized STI within said STI region substantially level with said substrate upper surface and over said x+2 total step trenches.

2. The method of claim 1, wherein said STI region has a width of from about 1500 to 10,000 Å, said first step trench has a depth below said structure of from about 1000 to 4000 Å, and said second step trench has a depth below said first step trench of from about 500 to 2000 Å.

3. The method of claim 1, wherein said steps e) and f) are repeated two more times to create four total step trenches; said STI region has a width of from about 1500 to 10,000 Å; said first step trench has a depth below said structure of from about 1000 to 4000 Å; said second step trench has a depth below said first step trench of from about 500 to 2000 Å; the third step trench has a depth below said second step trench of from about 500 to 2000 Å; and the fourth step trench has a depth below said third step trench of from about 500 to 2000 Å.

4. The method of claim 1, wherein said steps e) and f) are repeated two more times to create four total step trenches; said STI region has a width of from about 1500 to 10,000 Å; said first step trench has a depth below said structure of from about 2000 to 3000 Å; said second step trench has a depth below said first step trench of from about 800 to 1500 Å; the third step trench has a depth below said second step trench of from about 800 to 1500 Å; and the fourth step trench has a depth below said third step trench of from about 800 to 1500 Å.

5. The method of claim 1, wherein said masking layer is comprised of a material selected from the group consisting of polysilicon, nitride and silicon nitride.

6. The method of claim 1, wherein said masking layer is comprised of nitride and has a thickness of from about 500 to 2000 Å.

7. The method of claim 1, wherein said STI region has a width of from about 1500 to 10,000 Å, said first step trench side wall spacers have a base width of from about 300 to 1000 Å, and said second step trench side wall spacers have a base width of from about 300 to 1000 Å.

8. The method of claim 1, wherein said steps e) and f) are repeated two more times to create four total step trenches; said STI region has a width of from about 1500 to 10,000 Å; said first step trench side wall spacers have a base width of from about 300 to 1000 Å, said second step trench side wall spacers have a base width of from about 300 to 1000 Å; said third step trench side wall spacers have a base width of from about 300 to 1000 Å; and said fourth step trench side wall spacers have a base width of from about 300 to 1000 Å.

9. The method of claim 1, wherein said steps e) and f) are repeated two more times to create four total step trenches; said STI region has a width of from about 1500 to 10,000 Å; said first step trench side wall spacers have a base width of from about 400 to 600 Å, said second step trench side wall spacers have a base width of from about 400 to 600 Å; said third step trench side wall spacers have a base width of from about 400 to 600 Å; and said fourth step trench side wall spacers have a base width of from about 400 to 600 Å.

10. A method of forming a sloped staircase STI structure, comprising the steps of:
a) providing a substrate having an upper surface;
b) forming a patterned nitride masking layer over said substrate to define an STI region having a width from about 1500 to 10,000 Å; said patterned nitride masking layer having exposed sidewalls;
c) etching said substrate a first time through said masking layer to form a first step trench within said STI region; said first step trench having exposed sidewalls;
d) forming continuous side wall spacers on said exposed patterned masking layer and first step trench sidewalls;
e) etching said substrate a second time using said nitride masking layer and said continuous sidewall spacers as masks to form a second step trench within said STI region; said second step trench having exposed sidewalls;
f) forming second side wall spacers on said second step trench sidewalls;
g) repeating steps e) and f) x more times to create x+2 total step trenches and x+2 total side wall spacers on x+2 total step trench sidewalls;
h) removing said patterned nitride masking layer; and
i) forming a planarized STI within said STI region substantially level with said substrate upper surface and over said x+2 total step trenches.

11. The method of claim 10, wherein said STI region has a width of from about 1000 to 5000 Å, said first step trench has a depth below said structure of from about 1000 to 4000 Å, and said second step trench has a depth below said first step trench 18 of from about 500 to 2000 Å.

12. The method of claim 10, wherein said steps e) and f) are repeated two more times to create four total step trenches; said STI region has a width of from about 1500 to 10,000 Å; said first step trench has a depth below said structure of from about 1000 to 4000 Å; said second step trench has a depth below said first step trench of from about 500 to 2000 Å; the third step trench has a depth below said second step trench of from about 500 to 2000 Å; and the fourth step trench has a depth below said third step trench of from about 500 to 2000 Å.

13. The method of claim 10, wherein said steps e) and f) are repeated two more times to create four total step trenches; said first step trench has a depth below said structure of from about 2000 to 3000 Å; said second step trench has a depth below said first step trench of from about 800 to 1500 Å; the third step trench has a depth below said second step trench of from about 800 to 1500 Å; and the fourth step trench has a depth below said third step trench of from about 800 to 1500 Å.

14. The method of claim 10, wherein said masking layer has a thickness of from about 500 to 2000 Å.

15. The method of claim 10, wherein said STI region has a width of from about 1000 to 5000 Å, said first step trench side wall spacers have a base width of from about 300 to 1000 Å, and said second step trench side wall spacers have a base width of from about 300 to 1000 Å.

16. The method of claim 10, wherein said steps e) and f) are repeated two more times to create four total step trenches; said first step trench side wall spacers have a base width of from about 300 to 1000 Å, said second step trench side wall spacers have a base width of from about 300 to 1000 Å; said third step trench side wall spacers have a base width of from about 300 to 1000 Å; and said fourth step trench side wall spacers have a base width of from about 300 to 1000 Å.

17. The method of claim 10, wherein said steps e) and f) are repeated two more times to create four total step trenches; said first step trench side wall spacers have a base width of from about 400 to 600 Å, said second step trench side wall spacers have a base width of from about 400 to 600 Å; said third step trench side wall spacers have a base width of from about 400 to 600 Å; and said fourth step trench side wall spacers have a base width of from about 400 to 600 Å.

18. A method of forming a sloped staircase STI structure, comprising the steps of:
a) providing a substrate having an upper surface;
b) forming a patterned nitride masking layer over said substrate to define an STI region having a width from about 1500 to 10,000 Å; said patterned nitride masking layer having exposed sidewalls; said patterned nitride masking layer having a thickness of from about 500 to 2000 Å;
c) etching said substrate a first time through said masking layer to form a first step trench within said STI region; said first step trench having exposed sidewalls;
d) forming continuous side wall spacers on said exposed patterned masking layer and first step trench sidewalls;
e) etching said substrate a second time using said nitride masking layer and said continuous sidewall spacers as masks to form a second step trench within said STI region; said second step trench having exposed sidewalls;
f) forming second side wall spacers on said second step trench sidewalls;
g) repeating steps e) and f) two more times to create x+2 total step trenches and x+2 total side wall spacers on x+2 total step trench sidewalls;
h) removing said patterned nitride masking layer; and
i) forming a planarized STI within said STI region substantially level with said substrate upper surface and over said x+2 total step trenches.

19. The method of claim 18, wherein said STI region has a width of from about 1000 to 5000 Å, said first step trench has a depth below said structure of from about 1000 to 4000 Å, and said second step trench has a depth below said first step trench 18 of from about 500 to 2000 Å.

20. The method of claim 18, wherein said steps e) and f) are repeated two more times to create four total step trenches; said first step trench has a depth below said structure of from about 1000 to 4000 Å; said second step trench has a depth below said first step trench of from about 500 to 2000 Å; the third step trench has a depth below said second step trench of from about 500 to 2000 Å; and the fourth step trench has a depth below said third step trench of from about 500 to 2000 Å.

21. The method of claim 18, wherein said steps e) and f) are repeated two more times to create four total step trenches; said first step trench has a depth below said structure of from about 2000 to 3000 Å; said second step trench has a depth below said first step trench of from about 800 to 1500 Å; the third step trench has a depth below said second step trench of from about 800 to 1500 Å; and the fourth step trench has a depth below said third step trench of from about 800 to 1500 Å.

22. The method of claim 18, wherein said masking layer has a thickness of from about 1000 to 1500 Å.

23. The method of claim 18, wherein said STI region has a width of from about 1000 to 5000 521 , said first step trench side wall spacers have a base width of from about 300 to 1000 Å, and said second step trench side wall spacers have a base width of from about 300 to 1000 Å.

24. The method of claim 18, wherein said steps e) and f) are repeated two more times to create four total step trenches; said first step trench side wall spacers have a base width of from about 300 to 1000 Å, said second step trench side wall spacers have a base width of from about 300 to 1000 Å; said third step trench side wall spacers have a base width of from about 300 to 1000 Å; and said fourth step trench side wall spacers have a base width of from about 300 to 1000 Å.

25. The method of claim 18, wherein said steps e) and f) are repeated two more times to create four total step trenches; said first step trench side wall spacers have a base width of from about 400 to 600 Å, said second step trench side wall spacers have a base width of from about 400 to 600 Å; said third step trench side wall spacers have a base width of from about 400 to 600 Å; and said fourth step trench side wall spacers have a base width of from about 400 to 600 Å.
